(19) United States
(12) Patent Application Publication
(10) Pub. No.: US 2023/0343803 A1
(43) Pub. Date: Oct. 26, 2023

(54) SEMICONDUCTOR DEVICE, METHOD OF PRODUCING THE SAME, AND ELECTRONIC APPARATUS

(71) Applicant: SONY SEMICONDUCTOR SOLUTIONS CORPORATION, Kanagawa (JP)

(72) Inventors: Toshiaki IWAFUCHI, Kanagawa (JP); Atsushi FUJIWARA, Kumamoto (JP)

(73) Assignee: SONY SEMICONDUCTOR SOLUTIONS CORPORATION, Kanagawa (JP)

(21) Appl. No.: 18/043,474

(22) PCT Filed: Aug. 24, 2021
(86) PCT No.: PCT/JP2021/030885

§ 371 Date: Feb. 28, 2023

(30) Foreign Application Priority Data
Sep. 7, 2020 (JP) 2020-149888

(51) Int. Cl. H01L 27/146; H01L 23/00

(52) U.S. Cl. CPC H01L 27/14623; H01L 24/13; H01L 24/16; H01L 24/26; H01L 24/29; H01L 24/32; H01L 24/73; H01L 24/81; H01L 24/83; H01L 24/92; H01L 27/14685; H01L 27/1469; H01L 27/14634; H01L 27/14636; H01L 2224/13144; H01L 2224/13147; H01L 2224/16145; H01L 2224/26145; H01L 2224/2919; H01L 2224/32145; H01L 2224/73104; H01L 2224/73204; H01L 2224/8113; H01L 2224/83007; H01L 2224/83102; H01L 2224/83191; H01L 2224/92125; H01L 2924/1431; H01L 2924/182; H01L 2924/186

(57) ABSTRACT

The present technology relates to a semiconductor device that includes an underfill resin and a light-shielding resin and allows to achieve a decrease in device size, a method of producing the same, and an electronic apparatus. The semiconductor device includes: a substrate having a pixel region in which a plurality of pixels is arranged; and one or more chips flip-chip bonded to the substrate via a connection terminal. A material of a first resin that protects a back surface of the chip and a material of a second resin that protects a side surface of the chip are different from each other. The present technology is applicable to, for example, a semiconductor device in which an image sensor chip and a signal processing chip are flip-chip bonded to each other.

### TECHNICAL FIELD

The present technology relates to a semiconductor device, a method of producing the same, and an electronic apparatus, and particularly to a semiconductor device that includes an underfill resin and a light-shielding resin and allows to achieve a decrease in device size, a method of producing the same, and an electronic apparatus.

### BACKGROUND ART

A flip-chip mounting technology in which a chip and a substrate or chips are caused to face each other and they are electrically and physically connected to each other using bumps is known. This flip-chip mounting technology is suitable for increasing the density, miniaturization, speedup, and reducing the power consumption, and the like of a semiconductor device.

In a semiconductor device formed by a flip-chip mounting technology, a gap between the chip and the substrate or a gap between the chips is filled with an underfill resin for the purpose of protecting the bumps or the like (see, for example, Patent Literature 1). The underfill resin enters the gap between the chip and the substrate or the gap between the chips due to, for example, capillary action in the process of producing a semiconductor device. However, the underfill resin flows out around the flip-chip mounted chip.

The applicant of the present application has proposed, in Patent Literature 1, a structure in which a groove for damming the outflow of a resin is formed around a region where a chip is to be mounted. The groove for damming the outflow of a resin is referred to also as a dam.

### CITATION LIST

### Patent Literature

Patent Literature 1: Japanese Patent Application Laid-open No. 2018-147974

### DISCLOSURE OF INVENTION

### Technical Problem

The semiconductor device disclosed in Patent Literature 1 adopts a structure in which the upper surface and the side surface of a chip is covered with a light-shielding resin, in addition to an underfill resin injected between a substrate and the chip for the purpose of preventing adverse effects of reflected light from the chip.

In the structure in which the upper surface and the side surface of a chip is covered with a light-shielding resin, such as the one of the semiconductor device disclosed in Patent Literature 1, the increase in the thickness of a light-shielding resin on the upper surface of a chip in addition to the increase in the amount of resins required has resulted in an increase in device size. Further, since the amount of resins is large, the warpage of the lower substrate has become large, which has affected image quality.

The present technology has been made in view of the above-mentioned circumstances and it is an object thereof to achieve a decrease in device size while including an underfill resin and a light-shielding resin.

### Solution to Problem

A semiconductor device according to a first aspect of the present technology includes: a substrate having a pixel region in which a plurality of pixels is arranged; and one or more chips flip-chip bonded to the substrate via a connection terminal, in which a material of a first resin that protects a back surface of the chip and a material of a second resin that protects a side surface of the chip are different from each other.

A method of producing a semiconductor device according to a second aspect of the present technology includes: flip-chip bonding, via a connection terminal, a chip to a substrate having a pixel region in which a plurality of pixels is arranged; and coating a side surface of the chip using a second resin that is a material different from a first resin that protects a back surface of the chip.

In the second aspect of the present technology, a chip is flip-chip bonded, via a connection terminal, to a substrate having a pixel region in which a plurality of pixels is arranged, and a side surface of the chip is coated using a second resin that is a material different from a first resin that protects a back surface of the chip.

An electronic apparatus according to a third aspect of the present technology includes: a semiconductor device that includes a substrate having a pixel region in which a plurality of pixels is arranged, and one or more chips flip-chip bonded to the substrate via a connection terminal, in which a material of a first resin that protects a back surface of the chip and a material of a second resin that protects a side surface of the chip are different from each other.

In the first to third aspect of the present technology, a substrate having a pixel region in which a plurality of pixels is arranged and one or more chips flip-chip bonded to the substrate via a connection terminal are provided, and a material of a first resin that protects a back surface of the chip and a material of a second resin that protects a side surface of the chip are different from each other.

The semiconductor device and the electronic apparatus may be independent devices or may be modules to be incorporated into another apparatus.

### BRIEF DESCRIPTION OF DRAWINGS

FIG. 1 is a diagram showing a first embodiment of a semiconductor device to which the present technology is applied.

FIG. 2 is a top view of the semiconductor device in FIG. 1.

FIG. 3 is a diagram describing the effects of a light-shielding resin.

FIG. 4 is a diagram describing a method of producing the semiconductor device according to the first embodiment.

FIG. 5 is a diagram showing another semiconductor device according to a Comparative Example.

FIG. 6 is a diagram describing a method of producing the semiconductor device in FIG. 5.

FIG. 7 is a diagram describing the effects of the semiconductor device in FIG. 1.

FIG. 8 is a diagram showing a second embodiment of the semiconductor device to which the present technology is applied.

FIG. 9 is a diagram showing a third embodiment of the semiconductor device to which the present technology is applied.

FIG. 10 is a diagram describing chip sizes of the semiconductor devices according to the first to third embodiments.

FIG. 11 is a diagram describing resin applying positions of the semiconductor devices according to the first to third embodiments.

FIG. 12 is a diagram showing fourth to sixth embodiments of the semiconductor device to which the present technology is applied.

FIG. 13 is a diagram describing resin applying positions of the semiconductor devices according to the fourth to sixth embodiments.

FIG. 14 is a diagram showing a seventh embodiment of the semiconductor device to which the present technology is applied.

FIG. 15 is a diagram showing an eighth embodiment of the semiconductor device to which the present technology is applied.

FIG. 16 is a diagram showing a ninth embodiment of the semiconductor device to which the present technology is applied.

FIG. 17 is a block diagram showing a configuration example of an imaging device as an electronic apparatus to which the present technology is applied.

FIG. 18 is a diagram describing a usage example of the image sensor.

FIG. 19 is a view depicting an example of a schematic configuration of an endoscopic surgery system.

FIG. 20 is a block diagram depicting an example of a functional configuration of a camera head and a camera control unit (CCU).

FIG. 21 is a block diagram depicting an example of schematic configuration of a vehicle control system.

FIG. 22 is a diagram of assistance in explaining an example of installation positions of an outside-vehicle information detecting section and an imaging section.

### MODE(S) FOR CARRYING OUT THE INVENTION

Hereinafter, embodiments for carrying out the present technology (hereinafter, referred to as embodiments) will be described. Note that description will be made in the following order.
1. First embodiment of semiconductor device
2. Producing method according to first embodiment
3. Another semiconductor device according to Comparative Example
4. Second embodiment of semiconductor device
5. Third embodiment of semiconductor device
6. Fourth to sixth embodiments of semiconductor device
7. Seventh embodiment of semiconductor device
8. Eighth embodiment of semiconductor device
9. Ninth embodiment of semiconductor device
10. Conclusion
11. Application example to electronic apparatus
12. Application example to endoscopic surgery system
13. Application example to moving object

In the drawings referred to in the following description, the same or similar portions are denoted by the same or similar reference symbols. However, the drawings are schematic and the relationship between thicknesses and planar dimensions, the ratio of the thickness of each layer, and the like are different from the actual ones. Further, there are portions with different dimensional relationships and different ratios between the drawings in some cases.

Further, the definitions of directions such as up and down in the following description are merely definitions for convenience of description and do not limit the technical idea of the present disclosure. For example, the up and down are converted into the right and left and interpreted when an object is observed after being rotated by 90° and the up and down are reversed and interpreted when an object is observed after being rotated by 180°.

### 1. First Embodiment of Semiconductor Device

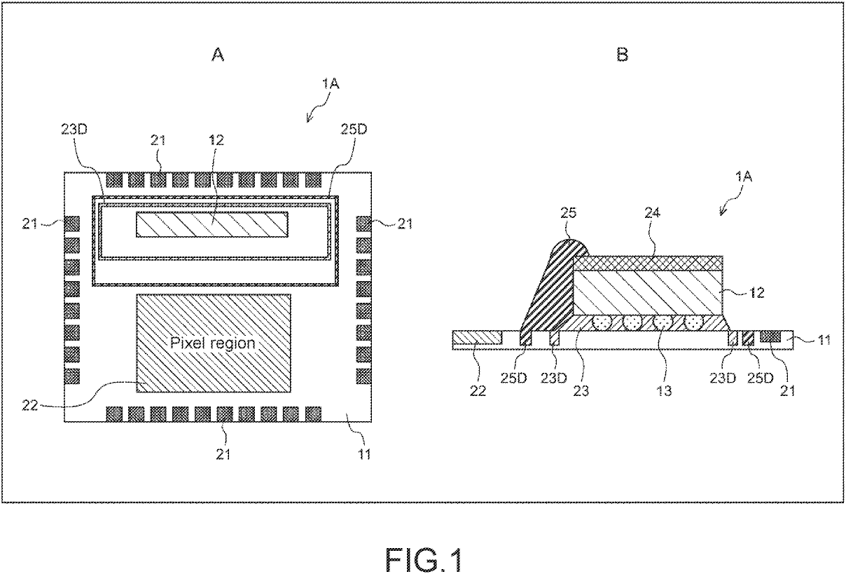

FIG. 1 is a diagram showing a first embodiment of the semiconductor device to which the present technology is applied.

Part A of FIG. 1 is a plan view of a semiconductor device 1A according to the first embodiment and Part B of FIG. 1 is a partial cross-sectional view of the semiconductor device 1A.

As shown in Part B of FIG. 1, the semiconductor device 1A includes a first semiconductor chip 11 and a second semiconductor chip 12 that are flip-chip bonded to each other via bumps 13 that are connection terminals. More specifically, the first semiconductor chip 11 and the second semiconductor chip 12 are disposed to face each other and the second semiconductor chip 12 is electrically and physically connected to the first semiconductor chip 11 via the bumps 13. As the material of the bump 13, solder Au, Cu, or the like can be used. It is desirable to use solder that can be flip-chip bonded with a low weight by reflowing, in order to reduce damage to a wiring layer and a transistor of the first semiconductor chip 11 on the lower side. The partial cross-sectional view of Part B of FIG. 1 is a cross-sectional view focusing on the bonded portion of the first semiconductor chip 11 and the second semiconductor chip 12. Illustration of part of the first semiconductor chip 11 far from the bonded portion of the second semiconductor chip 12 is omitted. In this embodiment, the first semiconductor chip 11 is, for example, an image sensor chip that generates an image signal corresponding the amount of incident light and outputs the generated image signal, and the second semiconductor chip 12 is, for example, a logic chip that performs predetermined signal processing using an image signal. In the following description, in order to facilitate distinction between chips, the first semiconductor chip 11 will be referred to as a sensor chip 11 and the second semiconductor chip 12 will be referred to as a logic chip 12.

As shown in Part A of FIG. 1, a plurality of electrode pads 21 is arranged in a row along the corresponding side of the rectangle on the outer periphery portion of the sensor chip 11. The electrode pads 21 are used for probe contact and wire bonding in an inspection process. A pixel region 22 in which pixels each including a photoelectric conversion unit that generates and accumulates photocharges corresponding to the amount of received light are two-dimensionally arranged in a matrix is formed on the inner side than the respective electrode pads 21 on the outer periphery portion of the sensor chip 11, and the logic chip 12 is flip-chip mounted on (flip-chip bonded to) a plane region different from the pixel region 22. Note that the plan view of Part A of FIG. 1 is a plan view with some portions omitted for the purpose of describing the respective portions constituting the semiconductor device 1A, as will be described in detail later.

As shown in Part B of FIG. 1, the gap of the bump 13 between the sensor chip 11 and the logic chip 12 is filled with an underfill resin 23 for protecting the bump 13. Then, as shown in the plan view of Part A of FIG. 1, a UF dam 23D that is a groove for damming the outflow of the underfill resin 23 is formed around the logic chip 12 of the sensor chip 11.

As shown in Part B of FIG. 1, the upper surface of the logic chip 12 is covered with a light-shielding resin 24. This light-shielding resin 24 is formed by attaching, to the upper surface of the logic chip 12, a tape (light-shielding tape) formed of a resin material that causes infrared light (IR) to be transmitted therethrough. The light-shielding resin 24 can be formed of a material such as an epoxy resin, an acrylic acid ester copolymer, silica (silicon oxide), and carbon black. The coefficient of thermal expansion of the light-shielding resin 24 at the time of heating and at normal temperature can be adjusted by adjusting the filling rate of a filler in the tape, and thus, the coefficient of thermal expansion of the light-shielding resin 24 is adjusted to be the same as the coefficient of thermal expansion of the logic chip 12. As a result, the resin material is adjusted so that the logic chip 12 does not warp when the tape-type light-shielding resin 24 is attached and cured. By suppressing the warpage of the chip, flip-chip bonding can be easily performed. In the logic chip 12, the surface to be bonded to the sensor chip 11 via the bumps 13 is the front surface side and the upper surface covered with the light-shielding resin 24 is the back surface side of the logic chip 12.

Further, in the semiconductor device 1A, a light-shielding resin 25 using a material different from that of the light-shielding resin 24 on the upper surface of the logic chip 12 is formed so as to cover the side surface of the logic chip 12 on the side of the pixel region 22 as shown in Part B of FIG. 1, and a resin dam 25D that is a groove for damming the outflow of the light-shielding resin 25 is formed on the outer side than the UF dam 23D formed around the logic chip 12 as shown in the plan view of Part A of FIG. 1.

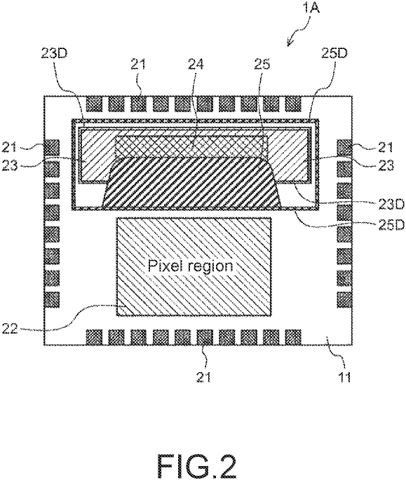

Note that the plan view of Part A of FIG. 1 is a diagram in which the light-shielding resin 24 and the light-shielding resin 25 on the upper surface of the logic chip 12 are omitted in order to describe the disposition relationship between the logic chip 12, the UF dam 23D, and the resin dam 25D. A diagram of the semiconductor device 1A according to the first embodiment as viewed from above without omitting these is as shown in FIG. 2. A plan view is described as shown in Part A of FIG. 1 including other embodiments described below in order to make the disposition of the logic chip 12, the UF dam 23D, and the resin dam 25D easier to understand.

As can be seen from Part B of FIG. 1 and FIG. 2, the light-shielding resin 25 covers also part of the upper surface (back surface) of the logic chip 12 so as to cover the entire side surface of one side on the side of the pixel region 22, of the four rectangular sides of the logic chip 12, and cover the corner between the side surface and the upper surface of the logic chip 12. In other words, the light-shielding resin 25 on the side surface covers part of the light-shielding resin 24 on the upper surface such that the height of the light-shielding resin 25 formed on the side surface is larger than that of the light-shielding resin 24 formed on the upper surface. As a result, the corner between the side surface of the logic chip 12 on the side of the pixel region 22 and the upper surface can be reliably covered. By reliably covering the corner between the side surface of the logic chip 12 on the side of the pixel region 22 and the upper surface, it is possible to significantly reduce the risk of flare generation.

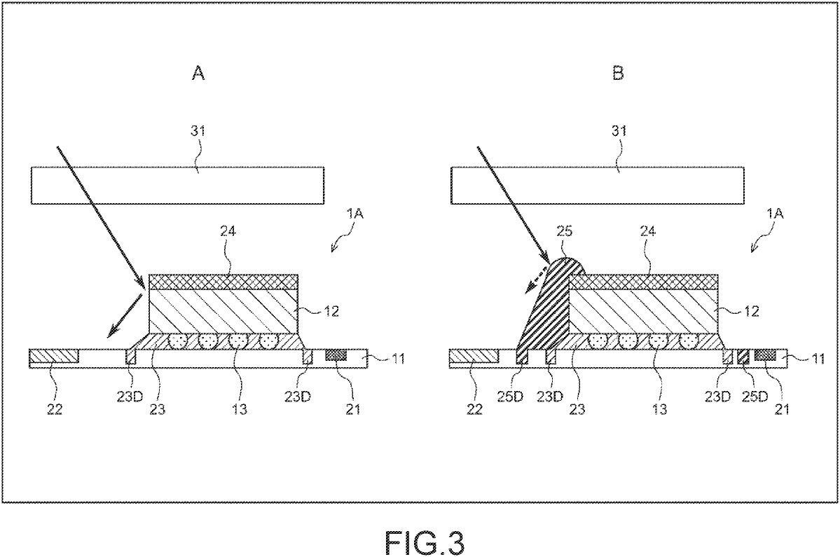

Part A of FIG. 3 is a cross-sectional view showing the reflected state of incident light in the case where the light-shielding resin 25 is not formed, and Part B of FIG. 3 is a cross-sectional view showing the reflected state of incident light in the case where the light-shielding resin 25 is formed.

In the case where the light-shielding resin 25 is not formed, as shown in Part A of FIG. 3, incident light directed toward the logic chip 12 is reflected by the side surface of the logic chip 12 and primary reflected light having high light intensity enters the pixel region 22 of the sensor chip 11.

Meanwhile, by covering the side surface of the logic chip 12 on the side of the pixel region 22 and the corner on the upper surface with the light-shielding resin 25, it is possible to prevent reflected light reflected by the side surface of the logic chip 12 from entering the pixel region 22 of the sensor chip 11, as shown in Part B of FIG. 3. As the material of the light-shielding resin 25, a material such as an epoxy resin, silica (silicon oxide), and carbon black can be used similarly to the light-shielding resin 24 on the upper surface, but a material different from that of the light-shielding resin 24 on the upper surface of the logic chip 12 is used. In the light-shielding resin 25, light is dispersed due to many recesses and projections on the surface formed by, for example, dispersing the size of the silica material and the reflectance is reduced by adding a coloring agent such as carbon black.

The material of the light-shielding resin 24 on the upper surface of the logic chip 12 and the material of the light-shielding resin 25 on the side surface are common in that they reduce the reflectance. By making these materials different from each other, materials according to the properties required for the light-shielding resin 24 and the light-shielding resin 25 such as suppression of flare, improvement in image quality, and improvement in bonding yield can be selected.

Note that although the light-shielding resin 25 is formed only on the side surface of the logic chip 12 on the side of the pixel region 22 and the corner on the upper surface in consideration of other effects in this embodiment, the light-shielding resin 25 may be formed not only on the side surface on the side of the pixel region 22 but also on another side surface when focusing only on the configuration in which the light-shielding resin 24 on the upper surface of the logic chip 12 and the light-shielding resin 25 on the side surface are formed using different materials. Even in this case, it is possible to achieve certain effects such as improvement in bonding yield, by using different materials for the light-shielding resin 24 on the upper surface and the light-shielding resin 25 on the outer periphery side surface.

In parts A and B of FIG. 3, a glass substrate 31 disposed above the logic chip 12 is a protective substrate that protects the semiconductor device 1A when packaged.

### 2. Production Method According to First Embodiment

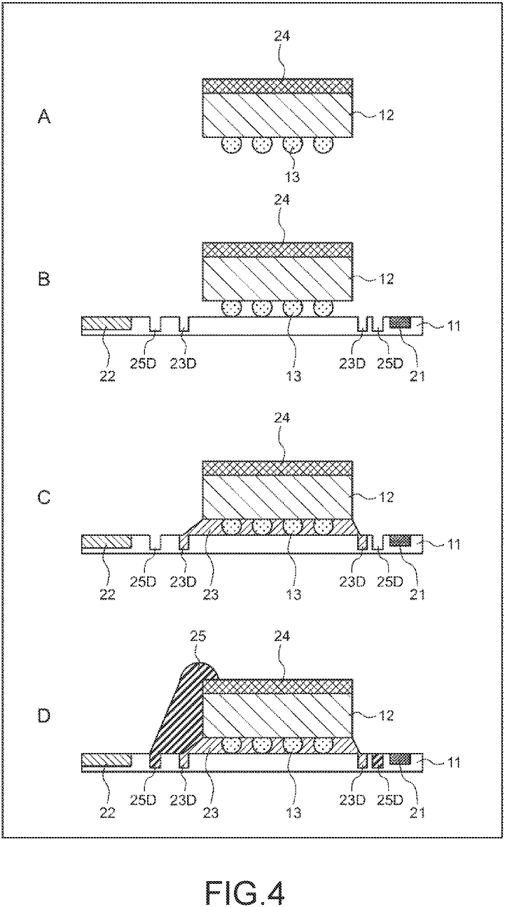

Next, a method of producing the semiconductor device 1A according to the first embodiment will be described with reference to FIG. 4.

First, as shown in Part A of FIG. 4, the tape-type light-shielding resin 24 is attached to the upper surface (back surface) of the logic chip 12 before being bonded to the sensor chip 11 and is cured by heating. The light-shielding resin 24 is formed of a thermosetting resin that is a material that causes infrared light to be transmitted therethrough.

Next, as shown in Part B of FIG. 4, the bumps 13 of the logic chip 12 are aligned with a predetermined electrode portion of the sensor chip 11, and the sensor chip 11 and the logic chip 12 are bonded to each other via the bumps 13. At this time, on the basis of the alignment mark formed on the upper surface of the sensor chip 11 and the alignment mark formed on the lower surface of the logic chip 12, the alignment in the plane direction and the adjustment of the height direction (gap adjustment) of the sensor chip 11 and the logic chip 12 are performed. More specifically, the positions in the plane direction are adjusted such that the alignment mark on the upper surface of the sensor chip 11 and the alignment mark on the lower surface of the logic chip 12 captured by an infrared camera have a predetermined disposition relationship. Further, the gap is adjusted by checking the height position when the alignment mark on the upper surface of the sensor chip 11 is focused and the height position when the alignment mark on the lower surface of the logic chip 121 is focused. The light-shielding resin 24 attached to the upper surface of the logic chip 12 is formed of a material that causes infrared light to be transmitted therethrough and the logic chip 12 that includes a semiconductor substrate formed of silicon or the like also causes infrared light to be transmitted therethrough, and thus, such alignment in the plane direction and the height direction is possible and the sensor chip 11 and the logic chip 12 can be bonded to each other with high accuracy.

Further, as described above, the filling rate of a filler in the light-shielding resin 24 is adjusted such that the coefficient of thermal expansion of the light-shielding resin 24 matches the coefficient of thermal expansion of the logic chip 12. As a result, since the warpage of the logic chip 12 at the time of heating and at normal temperature can be suppressed, it is possible to improve the yield of bonding between the sensor chip 11 and the logic chip 12 via the bumps 13.

Next, as shown in Part C of FIG. 4, the gap of the bumps 13 between the sensor chip 11 and the logic chip 12 is filled with the underfill resin 23 and the underfill resin 23 is cured. The underfill resin 23 is formed of a UV curable resin, a thermosetting resin, or the like. The underfill resin 23 flowing out of the logic chip 12 when an underfill resin is injected is dammed by the UF dam 23D.

Next, as shown in Part D of FIG. 4, the light-shielding resin 25 is applied on the side surface of the logic chip 12 on the side of the pixel region 22 and part of the upper surface of the logic chip 12 and then cured. The light-shielding resin 25 is also formed of a UV curable resin, a thermosetting resin, or the like. The light-shielding resin 25 flowing out toward the pixel region 22 of the sensor chip 11 when the light-shielding resin 25 is applied is dammed by the resin dam 25D.

As described above, the sensor chip 11 and the logic chip 12 are bonded to each other and protected by the underfill resin 23 and the light-shielding resin 25, thereby completing the semiconductor device 1A.

### 3. Another Semiconductor Device According to Comparative Example

Next, a configuration example of another semiconductor device will be described as a Comparative Example for describing the effects of the semiconductor device according to the present disclosure.

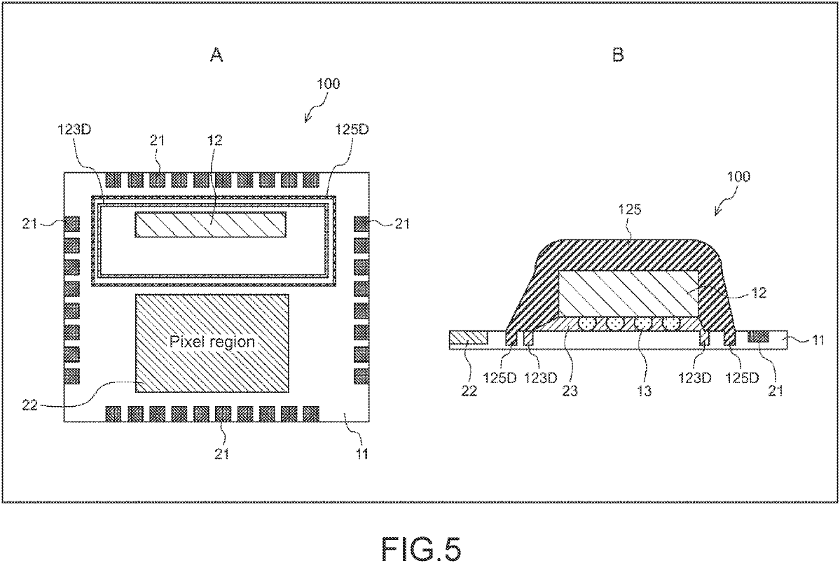

FIG. 5 shows a configuration of the above-mentioned semiconductor device disclosed in Patent Literature 1. Part A of FIG. 5 is a plan view of the semiconductor device disclosed in Patent Literature 1 and Part B of FIG. 5 is a partial cross-sectional view thereof.

In FIG. 5, portions common to those of the semiconductor device 1A shown in FIG. 1 are denoted by the same reference symbols, description of the portions is appropriately omitted, and description will focus on portions denoted by different reference symbols.

In a semiconductor device 100 in FIG. 5, as shown in Part B of FIG. 5, a light-shielding resin 125 is formed so as to cover the entire upper surface and the entire side surface of the logic chip 12. The light-shielding resin 125 corresponds to the light-shielding resin 24 on the upper surface and the light-shielding resin 25 on the side surface in the semiconductor device 1A in FIG. 1. The thickness of the light-shielding resin 125 on the upper surface of the logic chip 12 is large as shown in Part B of FIG. 5 in the case where the amount of resins to be applied is sufficient to cover the side surface of the logic chip 12. Note that although the light-shielding resin 125 on the upper surface of the logic chip 12 is formed flat in FIG. 5, the light-shielding resin 125 has a slightly recessed and projecting shape in some cases.

Further, in the semiconductor device 100 in FIG. 5, the plane position of the sensor chip 11 where a UF dam 123D for damming the outflow of the underfill resin 23 and a resin dam 125D for damming the outflow of the light-shielding resin 125 are formed is different from the positions is different from that of the UF dam 23D and the resin dam 25D in the semiconductor device 1A in FIG. 1. Specifically, the formation positions of the UF dam 23D and the resin dam 25D on the side of the pixel region 22 are away from each other in the semiconductor device 1A in FIG. 1, whereas the positions of the UF dam 123D and the resin dam 125D are close to each other in the semiconductor device 100 in FIG. 5.

In the case where the distance between the UF dam 123D and the resin dam 125D is short, when the UF dam 123D is filled with a large amount of the underfill resin 23, the light-shielding resin 125 to be applied after that easily climbs over the resin dam 125D. By separating the formation position of the UF dam 23D and the formation position of the resin dam 25D by a certain distance as in the semiconductor device 1A in FIG. 1, it is possible to more prevent the light-shielding resin 25 from climbing over the UF dam 23D.

The configuration of the semiconductor device 100 other than the formation positions of the UF dam 123D and the resin dam 125D and the light-shielding resin 125 is similar to that of the semiconductor device 1A in FIG. 1.

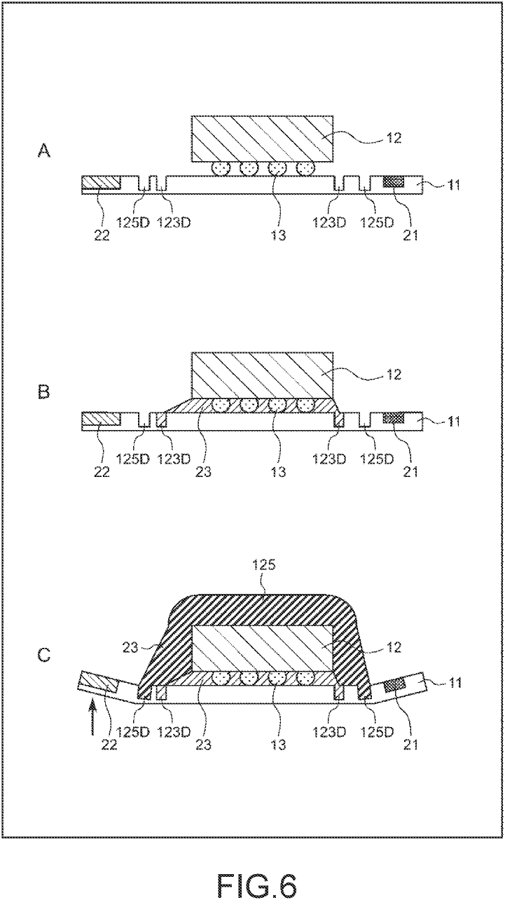

A method of producing the semiconductor device 100 in FIG. 5 will be described with reference to FIG. 6.

First, as shown in Part A of FIG. 6, the bumps 13 of the logic chip 12 are aligned with a predetermined electrode portion of the sensor chip 11, and the sensor chip 11 and the logic chip 12 are bonded to each other via the bumps 13. The method of the alignment is similar to that in the semiconductor device 1A described in FIG. 4.

Next, as shown in Part B of FIG. 6, the gap of the bumps 13 between the sensor chip 11 and the logic chip 12 is filled with the underfill resin 23 and the underfill resin 23 is cured. The underfill resin 23 flowing out of the logic chip 12 when an underfill resin is injected is dammed by the UF dam 123D.

Next, as shown in Part C of FIG. 6, the light-shielding resin 125 is applied on the entire side surface and the entire upper surface of the logic chip 12 and then cured. The light-shielding resin 125 is also formed of a UV curable resin, a thermosetting resin, or the like. The light-shielding resin 125 is applied in a plurality of lines along the longitudinal direction of the logic chip 12 so as to cover the entire upper surface and the entire side surface of the logic chip 12 and then cured.

The semiconductor device 100 is produced in this way.

In the semiconductor device 100, since the light-shielding resin 125 is applied so as to cover the entire upper surface and the entire side surface of the logic chip 12, the warpage of the sensor chip 11 is large as shown in Part C of FIG. 6 due to the curing shrinkage of the light-shielding resin 125. For this reason, the warpage of the pixel region 22 becomes large, which causes the focus position of the lens of the camera module to shift and affects image quality. That is, the focus position shifts between the central portion and the peripheral portion of the pixel region 22 and the image of the peripheral portion is deteriorated.

Meanwhile, in the semiconductor device 1A in FIG. 1, since the light-shielding resin 25 is applied only to the side surface of the logic chip 12 on the side of the pixel region 22 and part of the upper surface and cured, the warpage of the sensor chip 11 can be suppressed. Further, since the application area (application volume) of the light-shielding resin 25 is smaller than that of the semiconductor device 100, it is possible to reduce the amount of resins necessary for application, which contributes to the reduction in production cost.

Further, in the semiconductor device 100, when applying the light-shielding resin 125, it is necessary to apply the light-shielding resin 125 in a plurality of lines along the longitudinal direction of the logic chip 12 as described above, which increases the amount of resins necessary for application and prolongs the working time of the application process.

Meanwhile, since the light-shielding resin 25 of the semiconductor device 1A only needs to be applied only to the side surface of the logic chip 12 on the side of the pixel region 22 and part of the upper surface, it is necessary to apply the light-shielding resin 25 only in one line along the longitudinal direction of the logic chip 12 or a plurality of lines whose number is smaller than that of the semiconductor device 100, which shortens the working time of the application process. As a result, it is possible to shorten the production time of the semiconductor device 1A.

Further, in the semiconductor device 1A, since the tape-type light-shielding resin 24 is attached to the upper surface of the logic chip 12 and cured and then the logic chip 12 is bonded to the sensor chip 11, the gas generated when curing the light-shielding resin 25 can be reduced. As a result, it is possible to reduce the contamination of the electrode pad and the contamination of the on-chip lens of the pixel region 22.

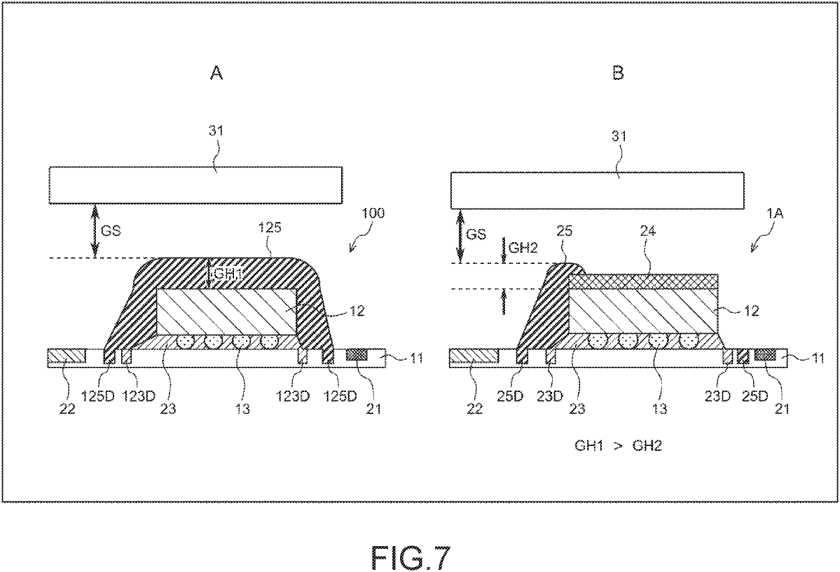

FIG. 7 is a partial cross-sectional view of the semiconductor device 100 and the semiconductor device 1A when packaged as camera module packages.

In the structure in which the entire upper surface and the entire side surface of the logic chip 12 are covered with the light-shielding resin 125 as in the semiconductor device 100 shown in Part A of FIG. 7, the amount of resins required increases and a thickness GH1 of the light-shielding resin on the upper surface of the logic chip 12 increases.

In the semiconductor device 1A shown in Part B of FIG. 7, since the tape-type light-shielding resin 24 is used on the upper surface of the logic chip 12 and it only needs to apply the light-shielding resin 25 only to the side surface on the side of the pixel region 22, a thickness GH2 of the light-shielding resin on the upper surface of the logic chip 12 can be made smaller than the thickness GH1 of the semiconductor device 100 (GH2 < GH1) even in the case where the light-shielding resin 25 is superimposed on the light-shielding resin 24 such that the height of the light-shielding resin 25 is larger than the height of the light-shielding resin 24. As a result, the height of the semiconductor device 1A can be made smaller than that of the semiconductor device 100. As shown in FIG. 7, assuming that a distance GS to the glass substrate 31 installed above the semiconductor device 1A or the semiconductor device 100 when packaged is constant, the package size of the semiconductor device 1A can be made smaller than that of the semiconductor device 100. That is, the semiconductor device 1A is capable of achieving a decrease in device size.

Further, since the height of the entire semiconductor device 1A is reduced, dust generated when the sensor chip 11 in the wafer state is diced into chips can be easily cleaned. As a result, for example, the contamination on the upper surface of the sensor chip 11 such as the electrode pad 21 and the pixel region 22 can be reduced and the yield can be improved.

### 4. Second Embodiment of Semiconductor Device

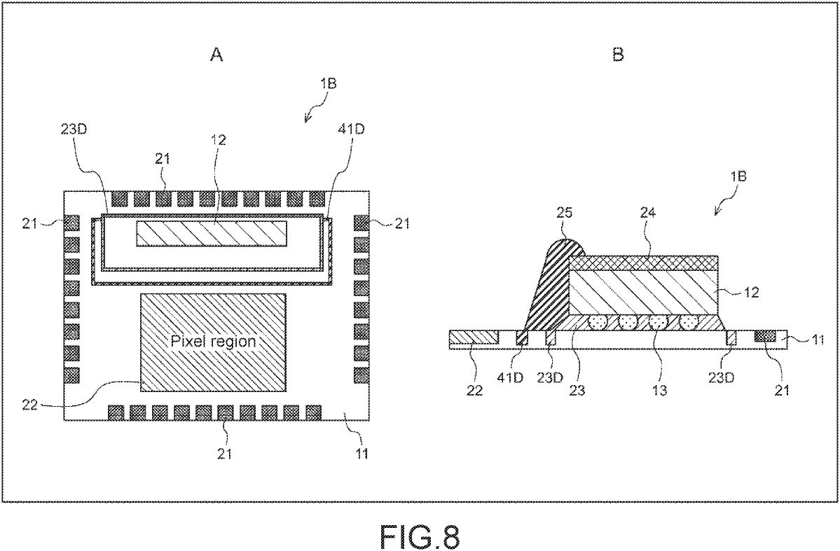

FIG. 8 is a diagram showing a second embodiment of the semiconductor device to which the present technology is applied.

Part A of FIG. 8 is a plan view of a semiconductor device 1B according to a second embodiment and Part B of FIG. 8 is a partial cross-sectional view of the semiconductor device 1B.

In FIG. 8, portions common to those of the semiconductor device 1A shown in FIG. 1 are denoted by the same reference symbols, description of the portions is appropriately omitted, and description will focus on portions denoted by different reference symbols.

The semiconductor device 1B in FIG. 8 has a configuration obtained by replacing the resin dam 25D of the semiconductor device 1A shown in FIG. 1 with a resin dam 41D. That is, in the semiconductor device 1B, the plane shape and disposition of the resin dam 41D are different from those of the resin dam 25D according to the first embodiment.

Specifically, in the semiconductor device 1A, as shown in Part A of FIG. 1, the resin dam 25D has been formed in a rectangular plane shape outside the UF dam 23D having a rectangular plane shape. Meanwhile, as shown in Part A of FIG. 8, the resin dam 41D according to the second embodiment is disposed in a U-shape outside three sides of the rectangular UF dam 23D other than the long side (hereinafter, referred to as a pixel-region opposite side.) of the rectangular UF dam 23D opposed to the long side on the side of the pixel region 22. Of the four sides of the rectangular UF dam 23D, the long side on the side of the pixel region 22 is referred to as a first side, the long side opposite to the first long side is referred to as a second side, and other two short sides opposite to each other are referred to as a third side and a fourth side. The resin dam 41D is not formed outside the second side of the rectangular UF dam 23D and the resin dam 41D is formed only outside the three sides of the first side, the third side, and the fourth side.

Since the light-shielding resin 25 is formed only on the side surface of the rectangular logic chip 12 on the side of the pixel region 22 and the corner on the upper surface of the logic chip 12 on the side of the side surface, the possibility that the light-shielding resin 25 flows to the side of the second side across the logic chip 12 is low considering the thixotropy and the like of the light-shielding resin 25. Since omitting the resin dam 25D on the side of the second side eliminates the need for a scape for disposing the resin dam 25D, the distance from the end surface of the logic chip 12 on the side of the second side to the end surface of the sensor chip 11 can be made shorter than that in the first embodiment, making it possible to further reduce the device size.

### 5. Third Embodiment of Semiconductor Device

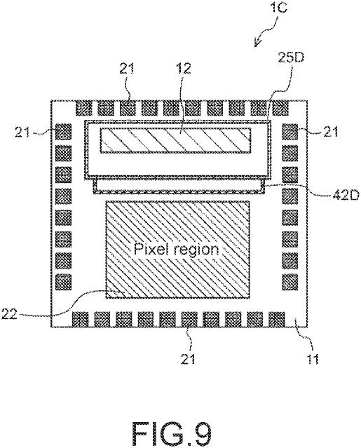

FIG. 9 is a diagram showing a third embodiment of the semiconductor device to which the present technology is applied.

FIG. 9 is a plan view of a semiconductor device 1C according to the third embodiment. The cross-sectional view of the semiconductor device 1C is omitted because it is similar to that in the second embodiment.

In FIG. 9, portions common to those of the above-mentioned semiconductor devices 1A and 1B are denoted by the same reference symbols, description of the portions is appropriately omitted, and description will focus on portions denoted by different reference symbols.

The semiconductor device 1C in FIG. 9 has a configuration obtained by replacing the resin dam 25D of the semiconductor device 1A shown in FIG. 1 with a resin dam 42D. That is, in the semiconductor device 1C, the plane shape and disposition of the resin dam 42D are different from those of the resin dam 25D according to the first embodiment.

The above-mentioned semiconductor device 1B according to the second embodiment has a configuration in which the resin dam 25D outside the second side of the rectangular UF dam 23D in the semiconductor device 1A is omitted to form the resin dam 41D in a U-shape.

Meanwhile, the semiconductor device 1C according to the third embodiment has a configuration in which not only the resin dam 25D outside the second side of the rectangular UF dam 23D in the semiconductor device 1A but also the resin dam 25D outside the third side and the fourth side that are two short sides is omitted to form the resin dam 42D only outside the first side on the side of the pixel region 22. The resin dam 42D is formed in an I-shape only outside the first side on the side of the pixel region 22.

Since omitting not only the outside of the second side of the rectangular UF dam 23D but also the outside of the third side and the fourth side eliminates the need for a space for disposing the resin dam 42D, the size of the sensor chip 11 not only in the longitudinal direction but also in the lateral direction in FIG. 9 can be reduced, making it possible to further reduce the device size.

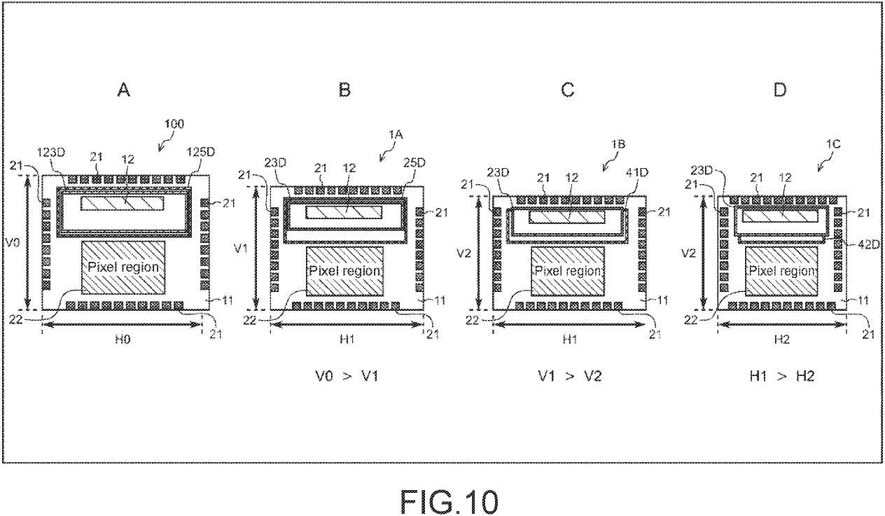

FIG. 10 is a plan view showing the sensor chips 11 of the semiconductor device 100 according to the Comparative Example and the semiconductor devices 1A to 1C according to the first to third embodiments.

When comparing the chip size of the semiconductor device 100 shown in Part A of FIG. 10 and the chip size of the sensor chip 11 of the semiconductor device 1A shown in Part B of FIG. 10 with each other, the regions (dam spaces) of the rectangular UF dam 23D and the resin dam 25D in the semiconductor device 1A can be made smaller than those in the semiconductor device 100 in which the entire upper surface and the entire outer periphery of the logic chip 12 are covered, because the region to which the light-shielding resin 25 is applied is only the side of the pixel region 22 of the logic chip 12. As a result, in the semiconductor device 1A, the chip size of the sensor chip 11 can be made smaller than that in the semiconductor device 100. That is, when the chip size of the sensor chip 11 of the semiconductor device 100 is defined as vertical V0 and horizontal H0 (hereinafter, described as V0 × H0 as appropriate.) and the chip size of the sensor chip 11 of the semiconductor device 1A is defined as V1 × H1, the relationships of V0 > V1 and H0 > H1 are satisfied.

When comparing the chip size of the semiconductor device 1A shown in Part B of FIG. 10 and the chip size of the sensor chip 11 of the semiconductor device 1B shown in Part C of FIG. 10 with each other, the chip size of the sensor chip 11 in the longitudinal direction in the semiconductor device 1B can be made smaller than that in the semiconductor device 1A, because the resin dam 41D is not formed outside the second side of the rectangular UF dam 23D. That is, when the chip size of the sensor chip 11 of the semiconductor device 1B is defined as V2 × H1, the relationship of V1 > V2 is satisfied with respect to the chip size V1 × H1 of the sensor chip 11 of the semiconductor device 1A.

When comparing the chip size of the sensor chip 11 of the semiconductor device 1B shown in Part C of FIG. 10 and the chip size of the sensor chip 11 of the semiconductor device 1C shown in Part D of FIG. 10 with each other, the chip size of the sensor chip 11 in the lateral direction in the semiconductor device 1C can be made smaller than that in the semiconductor device 1B, because the resin dam 42D is not formed not only outside the second side of the rectangular UF dam 23D but also outside the third side and the fourth side. That is, when the chip size of the sensor chip 11 of the semiconductor device 1C is defined as V2 × H2, the relationship of H1 > H2 is satisfied with respect to the chip size V2 × H1 of the sensor chip 11 of the semiconductor device 1B.

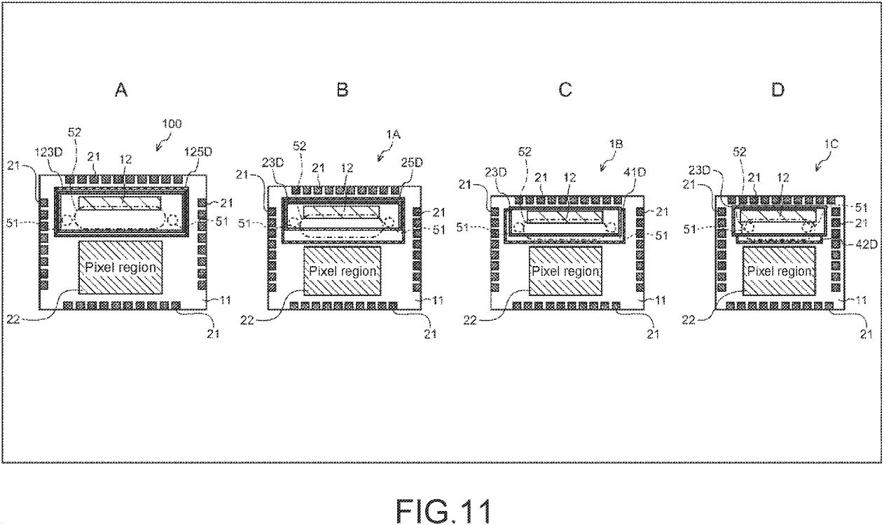

FIG. 11 is a plan view showing application positions of the underfill resin 23 and the light-shielding resin 25 in the semiconductor device 100 according to the Comparative Example and the semiconductor devices 1A to 1C according to the first to third embodiments.

In each plan view of Parts A to D of FIG. 11, a needle position 51 set when injecting the underfill resin 23 is indicated by a broken line and an application line 52 of the light-shielding resin 25 is indicated by a dot-dash line.

As shown in Parts A to D of FIG. 11, when injecting the underfill resin 23, the needle position 51 is set at a predetermined position between the logic chip 12 and the UF dam 23D or 123D. The underfill resin 23 discharged from the needle position 51 enters the gap of the bumps 13 between the sensor chip 11 and the logic chip 12 by capillary action.

The light-shielding resin 25 is applied from one end of the application line 52 indicated by the dot-dash line to the other end while moving the needle in a line along the side surface of the logic chip 12 on the side of the pixel region 22. The light-shielding resin 25 is applied so as to cover part of the logic chip 12. While the application line 52 of the light-shielding resin 25 is set on the inner side than the UF dam 123D in the semiconductor device 100, part of the application line 52 is set on the outer side of the UF dam 23D in each of the semiconductor devices 1A to 1C.

### 6. Fourth to Sixth Embodiments of Semiconductor Device

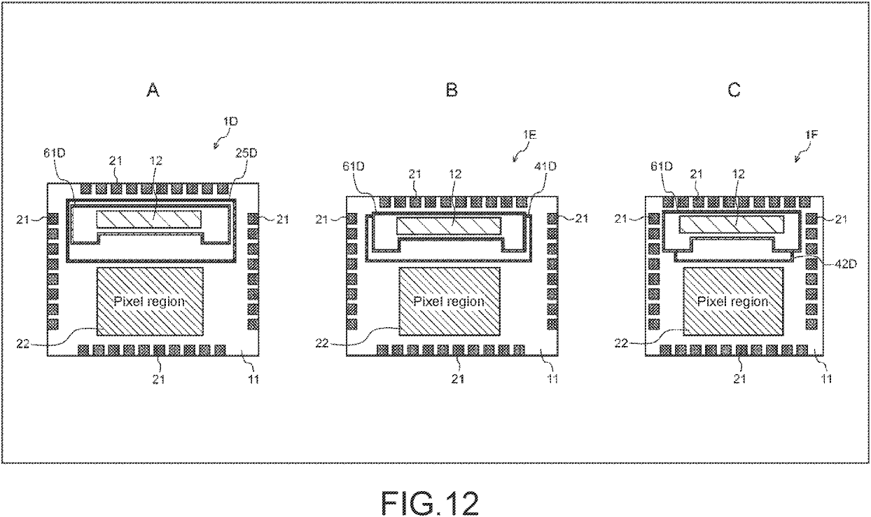

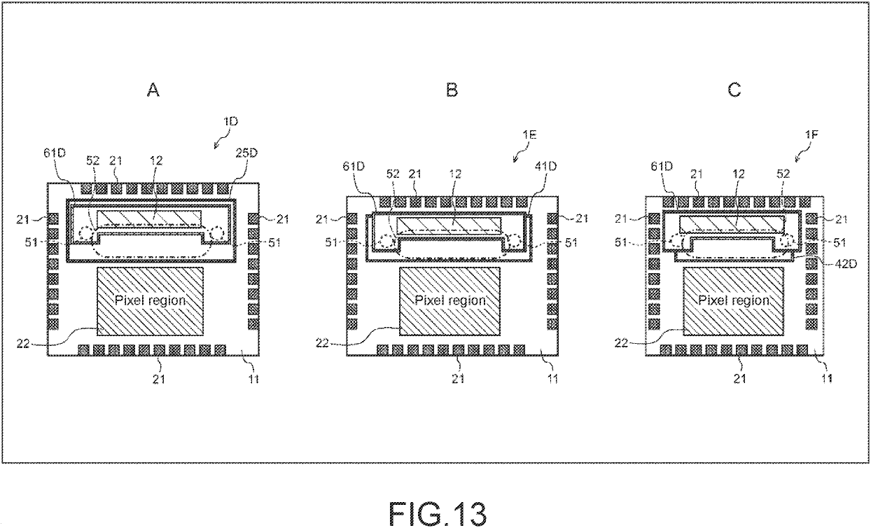

FIG. 12 and FIG. 13 are each a diagram showing fourth to sixth embodiments of the semiconductor device to which the present technology is applied.

Also in each embodiment in FIG. 12 and subsequent figures, portions common to those in the above-mentioned other embodiments are denoted by the same reference symbols and description of the portions is appropriately omitted.

Part A of FIG. 12 is a plan view of a semiconductor device 1D according to the fourth embodiment, Part B of FIG. 12 is a plan view of a semiconductor device 1E according to the fifth embodiment, and Part C of FIG. 12 is a plan view of a semiconductor device 1F according to the sixth embodiment.

Further, Parts A to C of FIG. 13 are each a plan view showing the needle position 51 of the underfill resin 23 and the application line 52 of the light-shielding resin 25 in the fourth to sixth embodiments in Parts A to C of FIG. 12, respectively.

Part A of FIG. 13 is a plan view showing the application position in the semiconductor device 1D shown in Part A of FIG. 12, Part B of FIG. 13 is a plan view showing the application position in the semiconductor device 1E shown in Part B of FIG. 12, and Part C of FIG. 13 is a plan view showing the application position in the semiconductor device 1F shown in Part C of FIG. 12.

The fourth to sixth embodiments in Parts A to C of FIG. 12 respectively have configurations in which the UF dam 23D according to the first to third embodiments is replaced with a UF dam 61D having another dam shape.

For example, as can be seen by comparing Part A of FIG. 1 and Part A of FIG. 12 with each other, the difference between the UF dam 23D and the UF dam 61D is that the UF dam 61D has a shape in which a wide space is provided between the UF dam 61D and the resin dam 25D by recessing part of the first side toward the side of the logic chip 12 while the UF dam 23D is disposed to have a rectangular plane shape.

The semiconductor device 1D according to the fourth embodiment shown in Part A of FIG. 12 has a configuration obtained by replating the UF dam 23D of the semiconductor device 1A according to the first embodiment shown in Part A of FIG. 1 with the UF dam 61D. That is, the semiconductor device 1D includes the UF dam 61D having a shape in which a wide space is provided between the UF dam 61D and the resin dam 25D by recessing part of the first side and the resin dam 25D having a rectangular plane shape.

The semiconductor device 1E according to the fifth embodiment shown in Part B of FIG. 12 has a configuration obtained by replacing the UF dam 23D of the semiconductor device 1B according to the second embodiment shown in Part A of FIG. 8 with the UF dam 61D. That is, the semiconductor device 1E includes the UF dam 61D having a shape in which a wide space is provided between the UF dam 61D and the resin dam 41D by recessing part of the first side and the resin dam 41D having a U-shape in which the outside of the second side is omitted.

The semiconductor device 1F according to the sixth embodiment shown in Part C of FIG. 12 has a configuration obtained by replacing the UF dam 23D of the semiconductor device 1C according to the third embodiment shown in FIG. 9 with the UF dam 61D. That is, the semiconductor device 1F includes the UF dam 61D having a shape in which a wide space is provided between the UF dam 61D and the resin dam 42D by recessing part of the first side and the resin dam 42D having an I-shape in which the outside of each of the second to fourth sides is omitted.

As can be seen from the needle position 51 of the underfill resin 23 and the application line 52 of the light-shielding resin 25 shown in Parts A to C of FIG. 13, in the fourth to sixth embodiments, the wide space of the UF dam 61D outside the logic chip 12 in the longitudinal direction corresponds to the needle position 51 of the underfill resin 23, and the wide space between the UF dam 61D and the resin dam 25D, 41D, or 42D formed by recessing the first side toward the side of the logic chip 12 corresponds to the application line 52 of the light-shielding resin 25. As described above, the plane shape of a resin dam in which wide spaces of the needle position 51 of the underfill resin 23 and the application line 52 of the light-shielding resin 25 are provide can be achieved.

Note that the sizes of the sensor chips 11 according to the fourth to sixth embodiments shown in Parts A to C of FIG. 12 are respectively similar to the sizes of the sensor chips 11 according to the first to third embodiments. The device size of the semiconductor device 1E according to the fifth embodiment is smaller than that of the semiconductor device 1D according to the fourth embodiment, and the device size of the semiconductor device 1F according to the sixth embodiment is smaller than that of the semiconductor device 1E according to the fifth embodiment.

### 7. Seventh Embodiment of Semiconductor Device

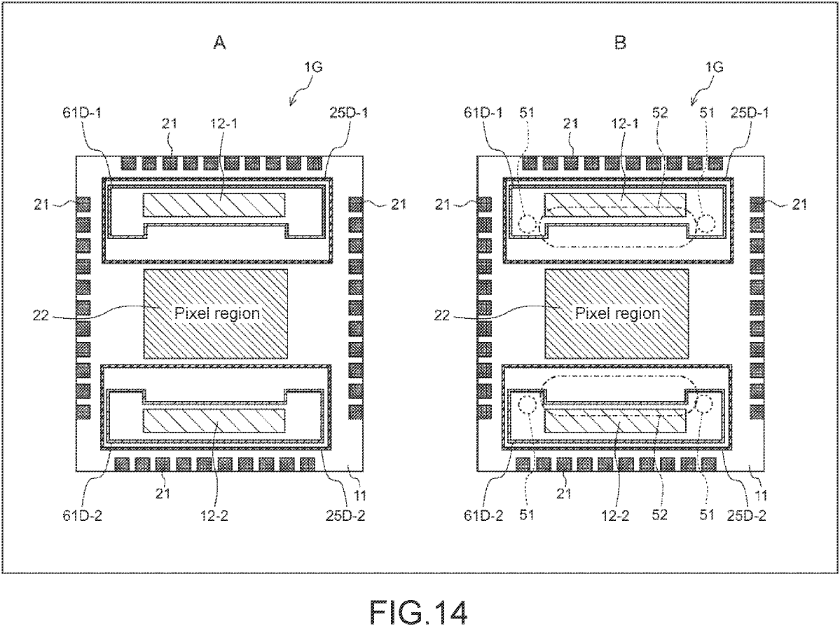

FIG. 14 is a diagram showing a seventh embodiment of the semiconductor device to which the present technology is applied.

Part A of FIG. 14 is a plan view of a semiconductor device 1G according to the seventh embodiment, and Part B of FIG. 14 is a plan view showing the needle position 51 of the underfill resin 23 and the application line 52 of the light-shielding resin 25 in the semiconductor device 1G.

The semiconductor device 1G according to the seventh embodiment shown in FIG. 14 has a configuration in which two logic chips 12 are flip-chip bonded on the sensor chip 11 serving as a base. As the shapes of a UF dam and a resin dam formed around the logic chip 12, the shapes of the UF dam 61D and the resin dam 25D in the semiconductor device 1D according to the fourth embodiment shown in Part A of FIG. 12 are adopted.

Here, the two logic chip 12 mounted on the sensor chip 11 are distinctively referred to as logic chips 12-1 and 12-2, and the UF dams 61D and the resin dams 25D formed around the logic chips 12-1 and 12-2 are distinctively referred to as UF dams 61D-1 and 61D-2 and resin dams 25D-1 and 25D-2.

In the semiconductor device 1G in FIG. 14, the two logic chips 12-1 and 12-2 are disposed to face each other with the pixel region 22 formed in the center of the sensor chip 11 interposed therebetween. The UF dam 61D-1 has a shape in which a wide space is provided between the UF dam 61D-1 and the resin dam 25D-1 by recessing the first side that is the long side on the side of the pixel region 22 toward the side of the logic chip 12-1. Similarly, the UF dam 61D-2 has a shape in which a wide space is provided between the UF dam 61D-2 and the resin dam 25D-2 by recessing the first side that is the long side on the side of the pixel region 22 toward the side of the logic chip 12-2. Each of the resin dams 25D-1 and 25D-2 have a rectangular plane shape.

The needle position 51 of the underfill resin 23 and the application line 52 of the light-shielding resin 25 are similar to those when the number of the logic chips 12 is one shown in Part A of FIG. 13. The needle position 51 of the underfill resin 23 is set in the wide space of the UF dam 61D outside the logic chip 12 in the longitudinal direction, and the application line 52 of the light-shielding resin 25 is set in the wide space between the UF dam 61D and the resin dam 25D.

### 8. Eighth Embodiment of Semiconductor Device

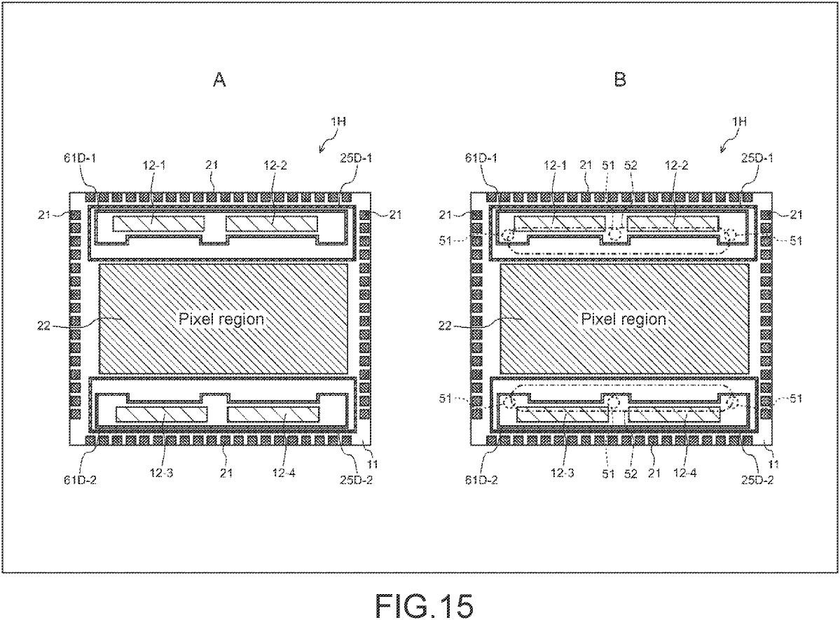

FIG. 15 is a diagram showing an eighth embodiment of the semiconductor device to which the present technology is applied.

Part A of FIG. 15 is a plan view of a semiconductor device 1H according to the eighth embodiment, and Part B of FIG. 15 is a plan view showing the needle position 51 of the underfill resin 23 and the application line 52 of the light-shielding resin 25 in the semiconductor device 1H.

The semiconductor device 1H according to the eighth embodiment shown in FIG. 15 has a configuration in which four logic chips 12 are flip-chip bonded on the sensor chip 11 serving as a base. As the shapes of a UF dam and a resin dam formed around the logic chip 12, the shapes of the UF dam 61D and the resin dam 25D in the semiconductor device 1D according to the fourth embodiment shown in Part A of FIG. 12 are adopted.

Here, in the case where four logic chips 12 are mounted on the sensor chip 11, two logic chips 12 and two logic chips 12 are disposed to face each other with the pixel region 22 interposed therebetween. When the four logic chips 12 are distinctively referred to as logic chips 12-1 to 12-4, the logic chips 12-1 and 12-2 laterally disposed and the logic chips 12-3 and 12-4 laterally disposed are disposed to face each other with the pixel region 22 interposed therebetween.

The UF dam 61D and the resin dam 25D are disposed so as to surround the two laterally disposed logic chips 12. Specifically, the UF dam 61D-1 and the resin dam 25D-1 are formed around the logic chips 12-1 and 12-2 and the UF dam 61D-2 and the resin dam 25D-2 are formed around the other logic chips 12-3 and 12-4.

The UF dam 61D-1 has a shape in which a wide space is provided between the UF dam 61D-1 and the resin dam 25D-1 by recessing the first side that is the long side on the side of the pixel region 22 toward the side of the logic chip 12 in the vicinity of the logic chips 12-1 and 12-2. Similarly, the UF dam 61D-2 also has a shape in which a wide space is provided between the UF dam 61D-2 and the resin dam 25D-2 by recessing the first side that is the long side on the side of the pixel region 22 toward the side of the logic chip 12 in the vicinity of the logic chips 12-3 and 12-4. Each of the resin dams 25D-1 and 25D-2 has a rectangular plane shape.

A total of three needle positions 51 of the underfill resin 23 are set at two places outside the two laterally disposed logic chips 12 and one place between the two logic chips 12 in one UF dam 61D. The application line 52 of the light-shielding resin 25 is set in a line along the side surfaces of the two laterally disposed logic chips 12 on the side of the pixel region 22 between the logic chip 12 and the resin dam 25D.

### 9. Ninth Embodiment of Semiconductor Device

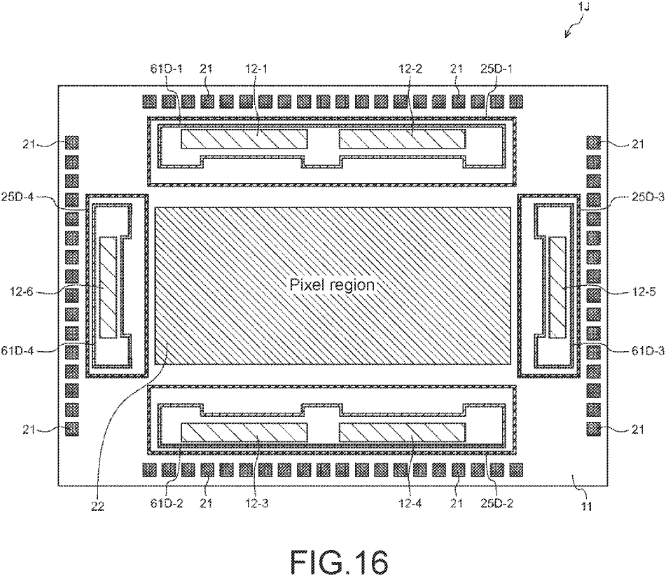

FIG. 16 is a diagram showing a ninth embodiment of the semiconductor device to which the present technology is applied.

FIG. 16 is a plan view of a semiconductor device 1J according to the ninth embodiment.

The semiconductor device 1J according to the ninth embodiment shown in FIG. 16 has a configuration in which six logic chips 12 are flip-chip bonded on the sensor chip 11 serving as a base. Specifically, with the pixel region 22 formed in the center of the sensor chip 11 as a center, two laterally disposed logic chips 12 are disposed in the vicinity of each of two sides opposite to each other and one logic chip 12 is disposed in the vicinity of each of the other two sides opposite to each other.

When the six logic chips 12 are distinctively referred to as logic chips 12-1 to 12-6, the laterally disposed logic chips 12-1 and 12-2 and the laterally disposed logic chips 12-3 and 12-4 are disposed to face each other with the pixel region 22 interposed therebetween. The UF dam 61D-1 and the resin dam 25D-1 are formed around the logic chips 12-1 and 12-2, and the UF dam 61D-2 and the resin dam 25D-2 are formed around the other logic chips 12-3 and 12-4. The configurations thereof are similar to those in the semiconductor device 1H according to the eighth embodiment in FIG. 15.

The logic chip 12-5 and the logic chip 12-6 are disposed in the vicinity of the remaining two sides opposite to each other to face each other with the pixel region 22 interposed therebetween. The UF dam 61D-3 and the resin dam 25D-3 are formed around the logic chip 12-5, and the UF dam 61D-4 and the resin dam 25D-4 are formed around the logic chip 12-6.

Each of the UF dams 61D-1 to 61D-4 has a shape in which a wide space is provided between the UF dam 61D and the resin dam 25D by being recessed toward the logic chip 12 in the vicinity of the logic chip 12. Each of the resin dams 25D-1 to 25D-4 has a rectangular plane shape.

Since the needle position 51 of the underfill resin 23 and the application line 52 of the light-shielding resin 25 are similar to those in Part A of FIG. 13 and Part B of FIG. 15, description thereof is omitted.

Note that although the UF dam 61D and the resin dam 25D according to the fourth embodiment shown in Part A of FIG. 12 have been adopted as an example of a UF dam and a resin dam in the case where a plurality of the logic chips 12 is bonded to the sensor chip 11 shown in FIG. 14 and FIG. 16, the configurations of a UF dam and a resin dam are not limited thereto. That is, a configuration in which the UF dams 23D and 61D and the resin dams 25D, 41D, and 42D according to the above-mentioned first to sixth embodiments are arbitrarily combined with each other as a UF dam and a resin dam for the disposition in which a plurality of the logic chips 12 is bonded to the sensor chip 11 can be adopted.

### 10. Conclusion

The semiconductor device 1 (semiconductor devices 1A to 1J) described above has the following configurations and effects.

The semiconductor device 1 is characterized by including one or more logic chips 12 flip-chip bonded on the sensor chip 11 and using resin materials for sealing and protecting the logic chip 12 that is an upper chip, which are different between the upper surface (back surface) of the logic chip 12 and the periphery (side surface). As a result, materials according to the properties required for each of the light-shielding resin 24 and the light-shielding resin 25 such as improvement in bonding yield can be selected by selecting materials that match the coefficient of thermal expansion of the logic chip 12 for the light-shielding resin 24 on the upper surface of the logic chip 12.

The light-shielding resin 25 applied around the logic chip 12 is formed not on all the four sides of the rectangle but only on the side surface facing the pixel region 22 and part of the upper surface on the side of the side surface. As a result, it is possible to reduce the amount of resins, reduce the production cost, and shorten the working time of the application process, thereby making it possible to shorten the production time.

Since a tape-type material is used as the light-shielding resin 24 on the upper surface of the logic chip 12 and cured and then the logic chip 12 is bonded to the sensor chip 11, it is possible to reduce the gas generate when curing the light-shielding resin 25 and reduce the contamination of the electrode pad and the contamination of the on-chip lens of the pixel region 22.

Further, since the warpage of the sensor chip 11 occurred when curing the light-shielding resin 25 can be suppressed, it is possible to reduce the shift of the focus position between the central portion and the peripheral portion of the pixel region 22 and suppress deterioration of image quality. Meanwhile, since the reflection of incident light that has entered the side surface of the logic chip 12 on the side of the pixel region 22 or the upper surface is suppressed by the light-shielding resin 25, it is possible to prevent flare from being generated.

Further, by forming the light-shielding resin 25 not on the four sides around the logic chip 12 but only on the side of the side surface facing the pixel region 22, since the installation area of the light-shielding resin 25 can be omitted for the three sides on which the light-shielding resin 25 is not formed, it is possible to contribute to the reduction of a chip size, and the number of chips produced per wafer can be increased, thereby contributing to cost reduction.

By using the light-shielding resin 24 using a tape material on the upper surface of the logic chip 12, as described with reference to FIG. 7, it is possible to reduce the device size (particularly, height) of the entire semiconductor device 1 and reduce the package size when packaged as a camera module package.

Although the above-mentioned semiconductor device 1 according to each embodiment has a configuration in which the second semiconductor chip 12 (logic chip 12) is flip-chip mounted on the first semiconductor chip 11 (sensor chip 11) that is a lower substrate serving as a base, the lower substrate as a base may be a substrate in the wafer state before singulation. That is, the technology of the present disclosure is applicable to both CoC (Chip on Chip) and CoW (Chip on Wafer). Further, although an example in which the first semiconductor chip 11 that is a lower substrate is a chip of an image sensor that generates an image signal corresponding to the amount of incident light and outputs the generated image signal has been described, the first semiconductor chip 11 may be a chip of another sensor chip that generates a received-light signal of incident light, e.g., a ranging sensor using a ToF (Time of Flight) method.

### 11. Application Example to Electronic Apparatus

The present technology does not necessarily need to be applied to a semiconductor device. That is, the present technology is applicable to general electronic apparatuses that use a semiconductor device as an image capturing unit (photoelectric conversion unit), such as imaging devices including a digital still camera and a video camera, a portable terminal device having an imaging function, and a copier that uses a semiconductor device as an image reading unit. The semiconductor device may be in a modular form having an imaging function in which the semiconductor device and an optical system are packaged together.

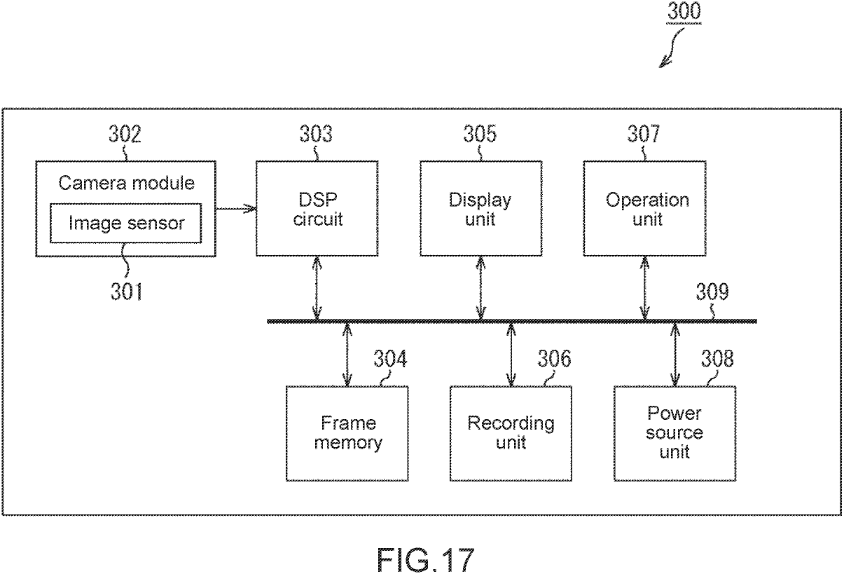

FIG. 17 is a block diagram showing a configuration example of an imaging device serving as an electronic apparatus to which the present technology is applied.

An imaging device 300 in FIG. 17 includes a camera module 302 and a DSP (Digital Signal Processor) circuit 303 that is a camera signal processing circuit. Further, the imaging device 300 also includes a frame memory 304, a display unit 305, a recording unit 306, an operation unit 307, and a power source unit 308. The DSP circuit 303, the frame memory 304, the display unit 305, the recording unit 306, the operation unit 307, and the power source unit 308 are connected to each other via a bus line 309.

An image sensor 301 in the camera module 302 captures incident light (image light) from a subject, converts the amount of incident light whose image is formed on an imaging surface into electrical signals in pixel unis, and outputs the electrical signal as a pixel signal to the DSP circuit 303. As this camera module 302, the above-mentioned semiconductor device 1, i.e., a device in which the second semiconductor chip 12 is flip-chip mounted on the first semiconductor chip 11, the back surface of the second semiconductor chip 12 is covered with the light-shielding resin 24 using a light-shielding tape, and not all the four sides of the first semiconductor chip 11 but only the side surface on one side and part of the upper surface on the side of the side surface are covered with the light-shielding resin 25 is adopted.

The display unit 305 includes, for example, a thin display such as an LCD (Liquid Crystal Display) and an organic EL (Electro Luminescence) display, and displays a moving image or a still image taken by the camera module 302. The recording unit 306 records the moving image or the still image taken by the camera module 302 on a recording medium such as a hard disk and a semi-conductor memory.

The operation unit 307 issues an operation command for various functions that the imaging device 300 has under the operation by a user. The power source unit 308 appropriately supplies various types of power serving as the operation power of the DSP circuit 303, the frame memory 304, the display unit 305, the recording unit 306, and the operation unit 307 to these supply targets.

As described above, by using, as the camera module 302, the semiconductor device 1 to which one of the above-mentioned embodiments is applied, it is possible to generate an image with high image quality while reducing the device size. Therefore, even in the imaging device 300 such as a video camera, a digital still camera, and a camera module for mobile devices such as mobile phones, it is possible to miniaturize the device and make the image quality of a captured image higher.

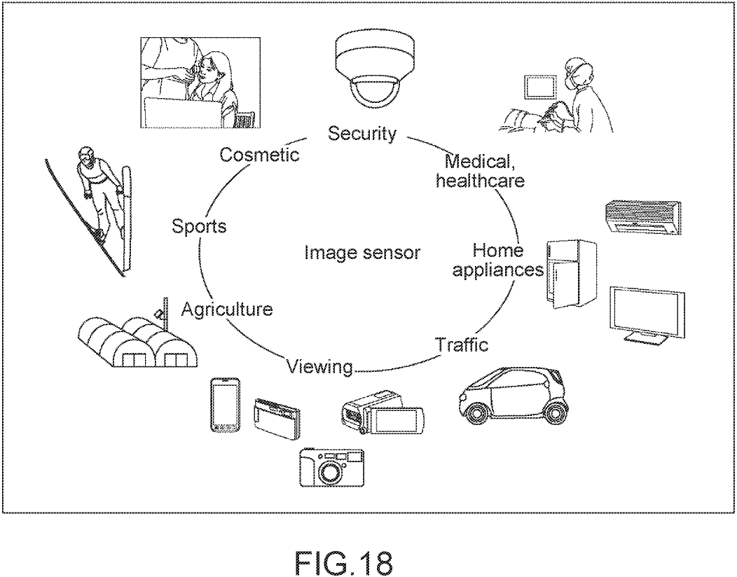

FIG. 18 a diagram showing a usage example of the camera module 302 in which the semiconductor device 1 is packaged.

The camera module 302 in which the above-mentioned semiconductor device 1 is packaged can be used in various cases for sensing light such as visible light, infrared light, infrared light, and X-rays, for example, as follows.
·Apparatus for taking images used for viewing, such as a digital camera and a portable device with a camera function
·Apparatus used for traffic purposes, such as an in-vehicle sensor for imaging the front, rear, surrounding, and interior of automobiles for safe driving such as automatic stopping or for recognizing the state of drivers, etc., a monitoring camera for monitoring traveling vehicles and roads, and a ranging sensor for ranging between vehicles, etc.
·Apparatus used in home appliances such as a TV, a refrigerator, and an air conditioner to image the gestures of users and perform device operations in accordance with the gestures
·Apparatus used for medical and healthcare purposes, such as an endoscope and an apparatus that performs angiography by receiving infrared light
·Apparatus used for security purposes, such as a monitoring camera for security purposes and a camera for personal identification purposes
·Apparatus used for cosmetic purposes, such as a skin measuring apparatus for imaging skin and a microscope for imaging scalp
·Apparatus used for sports purposes, such as an action camera for sports purposes and a wearable camera
·Apparatus used for agricultural purposes, such as a camera for monitoring the states of fields and crops

### 12. Application Example to Endoscopic Surgery System

The technology according to the present disclosure (the present technology) is applicable to various products. For example, the technology according to the present disclosure may be applied to an endoscopic surgery system.

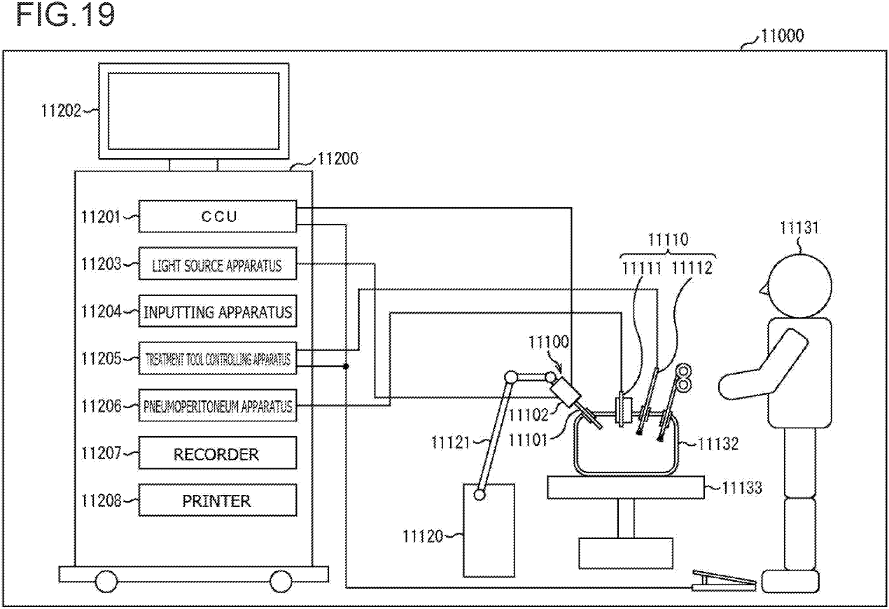

FIG. 19 is a view depicting an example of a schematic configuration of an endoscopic surgery system to which the technology according to an embodiment of the present disclosure (present technology) can be applied.

In FIG. 19, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

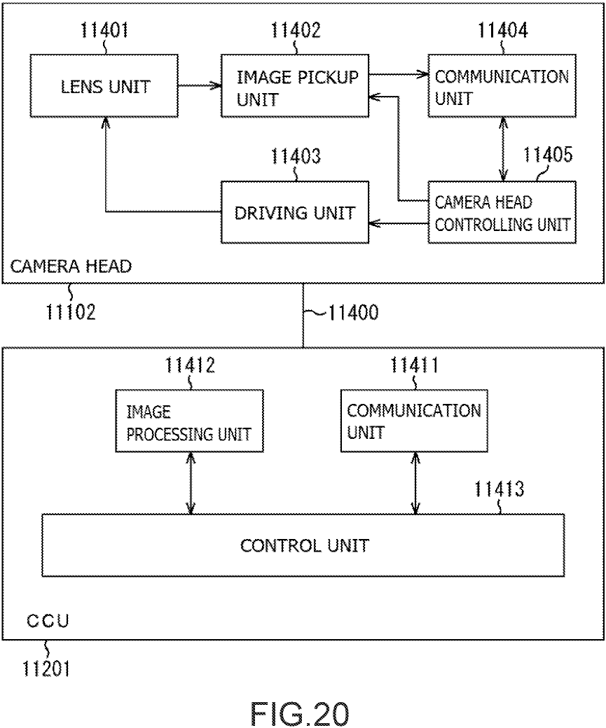

FIG. 20 is a block diagram depicting an example of a functional configuration of the camera head 11102 and the CCU 11201 depicted in FIG. 19.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image sensor. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of an endoscopic surgery system to which the technology according to the present disclosure can be applied has been described above. The technology according to the present disclosure is applicable to the lens unit 11401 and the image pickup unit 11402 of the camera head 11102, of the configurations described above. Specifically, as the lens unit 11401 and the image pickup unit 11402, the above-mentioned semiconductor device 1 or the camera module 302 can be applied. By applying the technology according to the present disclosure to the lens unit 11401 and the image pickup unit 11402, it is possible to acquire a clearer image of a surgical region while miniaturizing the camera head 11102.

Note that the endoscopic surgery system has been described here as an example, but the technology according to the present disclosure may be applied to, for example, a microscopic surgery system or the like.

### 13. Application Example to Moving Object

The technology according to the present disclosure (the present technology) is applicable to various products. For example, the technology according to the present disclosure may be realized as an apparatus mounted on any type of moving objects such as an automobile, an electric vehicle, a hybrid electric vehicle, a motorcycle, a bicycle, personal mobility, an airplane, a drone, a ship, and a robot.

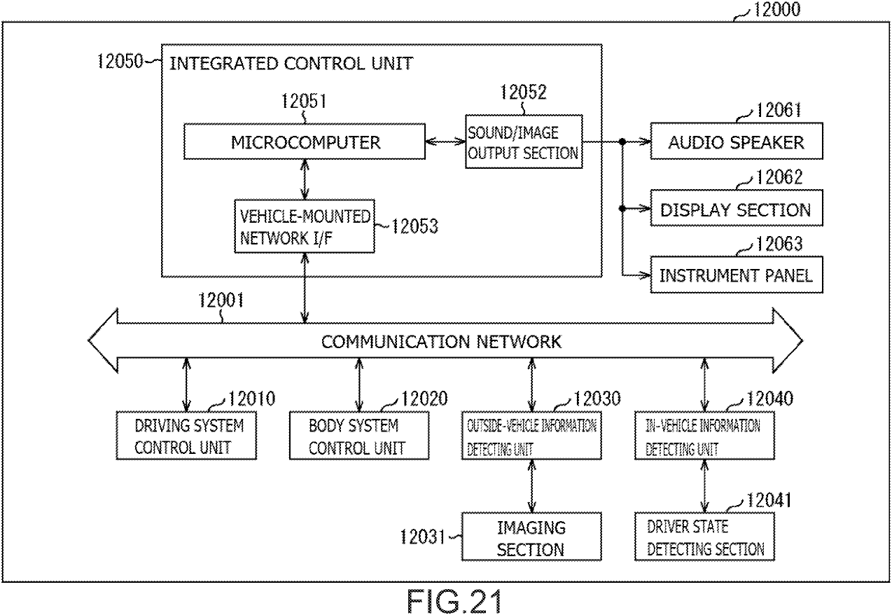

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

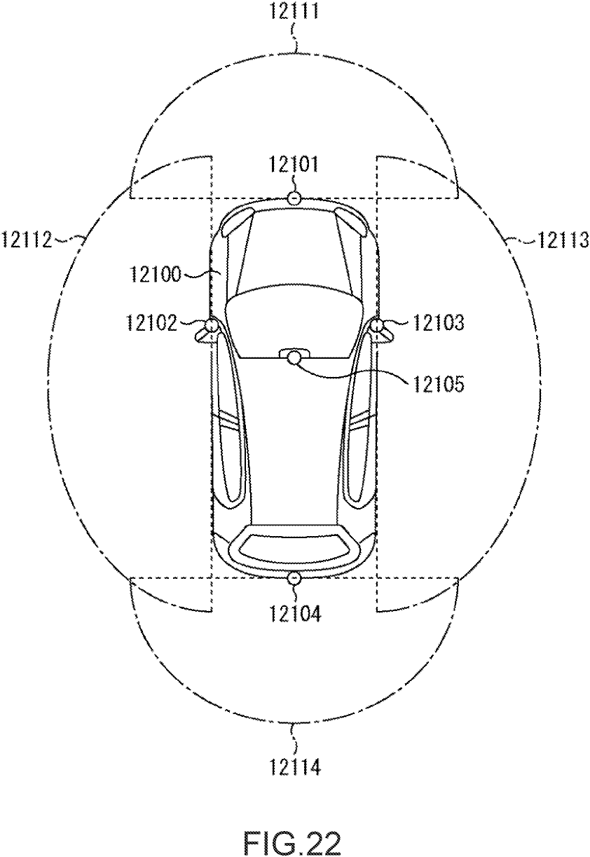

FIG. 22 is a diagram depicting an example of the installation position of the imaging section 12031.

In FIG. 22, the vehicle 12100 includes, as the imaging section 12031, imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The image of the front acquired by each of the imaging sections 12101 and 12105 is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird’s-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of a vehicle control system to which the technology according to the present disclosure can be applied has been described above. The technology according to the present disclosure is applicable to the imaging section 12031, of the configurations described above. Specifically, as the imaging section 12031, the above-mentioned semiconductor device 1 or the camera module 302 can be applied. By applying the technology according to the present disclosure to the imaging section 12031, it is possible to acquire an image that is easier to see and acquire distance information while achieving miniaturization. Further, it is possible to reduce the fatigue of drivers and improve the safety of drivers and vehicles by using the acquired image and distance information.

Further, the present technology is applicable not only to a semiconductor device that detects the distribution of the amount of incident light of visible light to take an image but also to general semiconductor devices (physical-quantity-distribution detecting devices) such as a semiconductor device that captures the distribution of the incident amount of infrared rays, X-rays, or particles as an image and a fingerprint detecting sensor that detects the distribution of another physical quantity such as a pressure and an electrostatic capacity to take an image in a broad sense.

Further, the present technology is applicable not only to a semiconductor device but also to general semiconductor devices including another semiconductor integrated circuit.

Embodiments of the present technology are not limited to the above-mentioned embodiments, and various modifications can be made without departing from the essence of the present technology.

For example, a form in which part of structures of the above-mentioned embodiments are appropriately combined with each other can be adopted.

Note that the effects described herein are merely illustrative and not restrictive, and other effects other than those described herein may be exerted.

It should be noted that the present technology may take the following configurations.

A semiconductor device, including:
a substrate having a pixel region in which a plurality of pixels is arranged; and
one or more chips flip-chip bonded to the substrate via a connection terminal,
a material of a first resin that protects a back surface of the chip and a material of a second resin that protects a side surface of the chip being different from each other.

The semiconductor device according to (1) above, in which

the second resin is formed on a side surface of the chip on a side of the pixel region.

The semiconductor device according to (2) above, in which

the second resin is also formed at a corner between the side surface of the chip on the side of the pixel region and an upper surface of the chip.

The semiconductor device according to any one of (1) to (3) above, in which

a height of the second resin formed on the side surface of the chip is larger than a height of the first resin that protects the back surface of the chip.

The semiconductor device according to any one of (1) to (4) above, in which

a coefficient of thermal expansion of the first resin is the same as a coefficient of thermal expansion of the chip.

The semiconductor device according to any one of (1) to (5) above, in which

the first resin is a material that causes infrared light to be transmitted therethrough.

The semiconductor device according to any one of (1) to (6) above, further including
an underfill resin that protects the connection terminal between the substrate and the chip, in which
the substrate includes a first resin dam for damming outflow of the underfill resin and a second resin dam for damming outflow of the second resin.

The semiconductor device according to (7) above, in which

each of the first resin dam and the second resin dam has a rectangular plane shape.

The semiconductor device according to (7) above, in which
the first resin dam has a rectangular plane shape, and
the second resin dam has a plane shape of a U-shape in which a side opposite to a side on a side of the pixel region, of four sides corresponding to the rectangular chip, is omitted.

The semiconductor device according to (7) above, in which
the first resin dam has a rectangular plane shape, and
the second resin dam has a plane shape of an I-shape formed only on a side on a side of the pixel region, of rectangular four sides of an outer periphery of the chip.

The semiconductor device according to (7) above, in which

the first resin dam has a plane shape obtained by recessing part of a side on a side of the pixel region toward a side of the chip, of rectangular four sides of an outer periphery of the chip.

The semiconductor device according to any one of (1) to (11) above, in which

a plurality of chips is flip-chip bonded to the substrate via connection terminals.

A method of producing a semiconductor device, including:
flip-chip bonding, via a connection terminal, a chip to a substrate having a pixel region in which a plurality of pixels is arranged; and
coating a side surface of the chip using a second resin that is a material different from a first resin that protects a back surface of the chip.

The method of producing a semiconductor device according to (13) above, further including

attaching the first resin to the back surface of the chip and then flip-chip bonding the chip to the substrate.

The method of producing a semiconductor device according to (13) or (14) above, in which

the first resin is a material that causes infrared light to be transmitted therethrough.

The method of producing a semiconductor device according to any one of (13) to (15) above, further including

attaching a tape-type resin material as the first resin and then curing the tape-type resin material.

The method of producing a semiconductor device according to any one of (13) to (16) above, in which

a coefficient of thermal expansion of the first resin is the same as a coefficient of thermal expansion of the chip.

The method of producing a semiconductor device according to any one of (13) to (17) above, in which
the substrate includes a first resin dam for damming outflow of an underfill resin that protects the connection terminal and a second resin dam for damming outflow of the second resin,
the first resin dam has a plane shape obtained by recessing part of a side on a side of the pixel region outside the rectangular chip toward a side of the chip, and
a needle position of the underfill resin is set in a space having no recess of the first resin dam outside the chip in a longitudinal direction.

The method of producing a semiconductor device according to any one of (13) to (17) above, in which
the substrate includes a first resin dam for damming outflow of an underfill resin that protects the connection terminal and a second resin dam for damming outflow of the second resin, the method further including
applying the second resin while moving a needle in a line along a side surface of the chip on a side of the pixel region.

An electronic apparatus, including:
a semiconductor device that includes
   a substrate having a pixel region in which a plurality of pixels is arranged, and
   one or more chips flip-chip bonded to the substrate via a connection terminal,
a material of a first resin that protects a back surface of the chip and a material of a second resin that protects a side surface of the chip being different from each other.

Reference Signs List

| 1 (1A to 1J) | semiconductor device |
|---|---|
| 11 | first semiconductor chip (sensor chip) |
| 12 | second semiconductor chip (logic chip) |
| 13 | bump |
| 21 | electrode pad |
| 22 | pixel region |
| 23 | underfill resin |
| 23D | UF dam |
| 24 | light-shielding resin |
| 25 | light-shielding resin |
| 25D | resin dam |
| 31 | glass substrate |
| 41D | resin dam |
| 42D | resin dam |
| 51 | needle position |
| 52 | application line |
| 61D | UF dam |
| 300 | imaging apparatus |
| 302 | camera module |

What is claimed is:

1. A semiconductor device, comprising:
a substrate having a pixel region in which a plurality of pixels is arranged; and
one or more chips flip-chip bonded to the substrate via a connection terminal,
a material of a first resin that protects a back surface of the chip and a material of a second resin that protects a side surface of the chip being different from each other.

2. The semiconductor device according to claim 1, wherein
the second resin is formed on a side surface of the chip on a side of the pixel region.

3. The semiconductor device according to claim 2, wherein
the second resin is also formed at a corner between the side surface of the chip on the side of the pixel region and an upper surface of the chip.

4. The semiconductor device according to claim 1, wherein
a height of the second resin formed on the side surface of the chip is larger than a height of the first resin that protects the back surface of the chip.

5. The semiconductor device according to claim 1, wherein
a coefficient of thermal expansion of the first resin is the same as a coefficient of thermal expansion of the chip.

6. The semiconductor device according to claim 1, wherein
the first resin is a material that causes infrared light to be transmitted therethrough.

7. The semiconductor device according to claim 1, further comprising
an underfill resin that protects the connection terminal between the substrate and the chip, wherein
the substrate includes a first resin dam for damming outflow of the underfill resin and a second resin dam for damming outflow of the second resin.

8. The semiconductor device according to claim 7, wherein
each of the first resin dam and the second resin dam has a rectangular plane shape.

9. The semiconductor device according to claim 7, wherein
the first resin dam has a rectangular plane shape, and
the second resin dam has a plane shape of a U-shape in which a side opposite to a side on a side of the pixel region, of four sides corresponding to the rectangular chip, is omitted.

10. The semiconductor device according to claim 7, wherein
the first resin dam has a rectangular plane shape, and
the second resin dam has a plane shape of an I-shape formed only on a side on a side of the pixel region, of four sides corresponding to the rectangular chip.

11. The semiconductor device according to claim 7, wherein
the first resin dam has a plane shape obtained by recessing part of a side on a side of the pixel region toward a side of the chip, of four sides corresponding to the rectangular chip.

12. The semiconductor device according to claim 1, wherein
a plurality of chips is flip-chip bonded to the substrate via connection terminals.

13. A method of producing a semiconductor device, comprising:
flip-chip bonding, via a connection terminal, a chip to a substrate having a pixel region in which a plurality of pixels is arranged; and
coating a side surface of the chip using a second resin that is a material different from a first resin that protects a back surface of the chip.

14. The method of producing a semiconductor device according to claim 13, further comprising
attaching the first resin to the back surface of the chip and then flip-chip bonding the chip to the substrate.

15. The method of producing a semiconductor device according to claim 13, wherein
the first resin is a material that causes infrared light to be transmitted therethrough.

16. The method of producing a semiconductor device according to claim 14, further comprising
attaching a tape-type resin material as the first resin and then curing the tape-type resin material.

17. The method of producing a semiconductor device according to claim 13, wherein
a coefficient of thermal expansion of the first resin is the same as a coefficient of thermal expansion of the chip.

18. The method of producing a semiconductor device according to claim 13, wherein
the substrate includes a first resin dam for damming outflow of an underfill resin that protects the connection terminal and a second resin dam for damming outflow of the second resin,
the first resin dam has a plane shape obtained by recessing part of a side on a side of the pixel region outside the rectangular chip toward a side of the chip, and
a needle position of the underfill resin is set in a space having no recess of the first resin dam outside the chip in a longitudinal direction.

19. The method of producing a semiconductor device according to claim 13, wherein
the substrate includes a first resin dam for damming outflow of an underfill resin that protects the connection terminal and a second resin dam for damming outflow of the second resin, the method further comprising
applying the second resin while moving a needle in a line along a side surface of the chip on a side of the pixel region.

20. An electronic apparatus, comprising:
a semiconductor device that includes
a substrate having a pixel region in which a plurality of pixels is arranged, and
one or more chips flip-chip bonded to the substrate via a connection terminal,
a material of a first resin that protects a back surface of the chip and a material of a second resin that protects a side surface of the chip being different from each other.
